(19) United States
(12) Patent Application Publication
(10) Pub. No.: US 2013/0120683 A1
(43) Pub. Date: May 16, 2013

(54) PIXEL STRUCTURE AND DISPLAY PANEL

(71) Applicant: AU OPTRONICS CORPORATION, Hsinchu (TW)

(72) Inventors: Shiuan-Fu Lin, New Taipei City (TW); Cheng-Yue Lin, New Taipei City (TW); Kuei-Bai Chen, New Taipei City (TW)

(73) Assignee: AU OPTRONICS CORPORATION, Hsinchu (TW)

(21) Appl. No.: 13/645,449

(22) Filed: Oct. 4, 2012

(30) Foreign Application Priority Data
Nov. 11, 2011 (TW) 100141259

(51) Int. Cl. H01L 33/08; G02B 26/00; G02F 1/136

(52) U.S. Cl. 349/46; 359/296; 359/290; 257/98; 257/E33.001

(57) ABSTRACT

A pixel structure including a substrate, at least one switch, at least one color filter, a passivation layer and at least one pixel electrode is provided. The substrate has at least one sub-area. The switch is disposed on the sub-area and has an gate insulator that covers the sub-area of the substrate. The switch is electrically connected to a scan line and a data line. The color filter is disposed on the gate insulator, wherein the color filter is in contact with the switch and the gate insulator. A contact via is formed in the color filter and the gate insulator such that a part of the switch is exposed thereby. The pixel electrode is disposed on the passivation layer and electrically connected to the switch through the contact via. A display panel including the above-mentioned pixel structure is also provided.

### CROSS-REFERENCE TO RELATED APPLICATION

This application claims the priority benefit of Taiwan application serial no. 100141259, filed on Nov. 11, 2011. The entirety of the above-mentioned patent application is hereby incorporated by reference herein and made a part of this specification.

### BACKGROUND OF THE INVENTION

1. Field of the Invention

The present invention relates to a pixel structure. More particularly, the present invention relates to a pixel structure having a color filter.

2. Description of Related Art

With the advancement in technology, bulky cathode ray tube (CRT) displays have been gradually replaced by flat panel displays including liquid crystal displays (LCD), organic electro-luminescent displays, field emission displays (FED), plasma display panels (PDP). Generally speaking, the conventional LCD panel is formed by a color filter substrate, a thin film transistor (TFT) array substrate, and a liquid crystal layer sandwiched therebetween. Recently, techniques of color filter on array (COA) and black matrix on array (BOA) have been proposed.

COA technique includes fabrications of a COA substrate and a color filter, wherein fabrication of the COA substrate includes forming a first patterned metal layer (including a scan line, a gate, a lower capacitance electrode, etc.), a gate insulator, a patterned semiconductor layer, a second patterned metal layer (including a data line, a source, a drain, an upper capacitance electrode, etc.), a first passivation layer, a second passivation layer and a pixel electrode, and the color filter is formed between the first passivation layer and the second passivation layer. In detail, after forming the first passivation layer, manufacturers must transfer the substrate to another production line for forming the color filter. After forming the color filter, manufacturers must transfer the substrate back to the original production line for forming the second passivation layer and the pixel electrode.

Based on the above, the COA technique nowadays usually faces the problems of high manufacturing cost, therefore, how to reduce the cost of COA technique effectively becomes an important issue to be solved.

### SUMMARY OF THE INVENTION

The application provides a pixel structure and a display panel having the same.

The application provides a pixel structure including a substrate, at least one switch, at least one color filter and at least one pixel electrode. The substrate has at least one sub-area. The switch is disposed on the sub-area and has a gate insulator that covers the sub-area of the substrate. The switch is electrically connected to at least one data line and at least one scan line. The color filter is disposed on the gate insulator, wherein the color filter is in contact with the switch and in contact with a part of the gate insulator. The passivation layer is disposed on the color filter, wherein a contact via is formed in the color filter and the passivation layer such that a part of the switch is exposed thereby. The pixel electrode is disposed on the passivation layer and electrically connected to the switch through the contact via.

According to an embodiment of the application, the thickness of the gate insulator is about 3500 angstroms.

According to an embodiment of the application, when the thickness of the gate insulator is about 3500 angstroms, the thickness of the passivation layer is between about 900 to about 1100 angstroms.

According to an embodiment of the application, when the thickness of the gate insulator is about 3500 angstroms, the thickness of the passivation layer is between about 700 to about 1000 angstroms.

According to an embodiment of the application, the thickness of the gate insulator is greater than or substantially equal to 3500 angstroms, and the thickness of the gate insulator is smaller than 4000 angstroms. In the present embodiment, the thickness of the passivation layer is between about 900 to about 1100 angstroms, or the thickness of the passivation layer is between about 700 to about 1000 angstroms.

The application further provides a display panel including a plurality of pixel structures described above, a display medium layer and an opposite substrate. The display medium layer is disposed on the pixel structures, and the opposite substrate is disposed on the display medium layer.

According to an embodiment of the application, the material of the display medium layer is, for example, liquid crystal material, self-illuminating material, electrophoresis material or electrowetting material.

To make the above and other features and advantages of the application more comprehensible, several embodiments accompanied with figures are detailed as follows.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic cross-sectional view illustrating a pixel structure according to an embodiment of the invention.

FIG. 2 is a schematic view illustrating the layout of a scan line, a data line, a switch, and a pixel electrode of a pixel structure.

FIG. 3 is a schematic cross-sectional view of a display panel according to an embodiment of the present invention.

### DESCRIPTION OF EMBODIMENTS

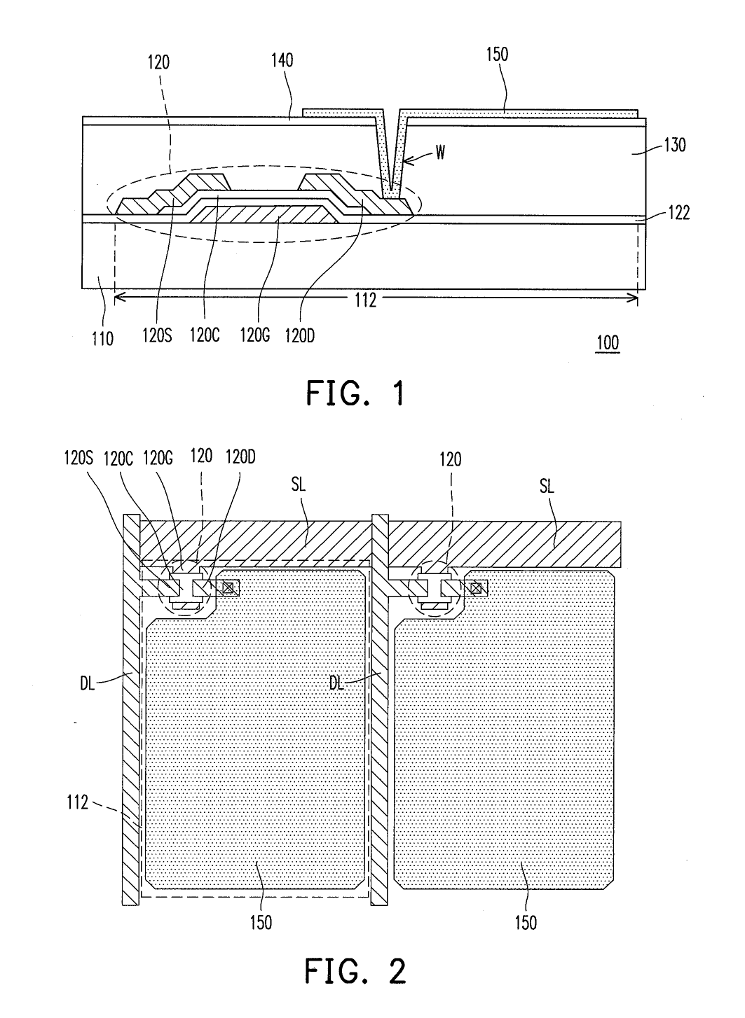

FIG. 1 is a schematic cross-sectional view illustrating a pixel structure according to an embodiment of the invention. FIG. 2 is a schematic view illustrating the specific layout of a scan line, a data line, a switch, and a pixel electrode. Please refer to FIG. 1 and FIG. 2, in the present embodiment, a pixel structure 100 includes a substrate 110, at least one switch 120, at least one color filter 130, a passivation layer 140 and at least one pixel electrode 150. The substrate 110 has at least one sub-area 112. The switch 120 is disposed on the sub-area 112 and has a gate insulator 122 that covers the sub-area 112 of the substrate 110. The switch 120 is electrically connected to at least one data line DL (as illustrated in FIG. 2) and at least one scan line SL (as illustrated in FIG. 2). The color filter 130 is disposed on the gate insulator 122, wherein the color filter 130 contacts the switch 120 and contacts a part of the gate insulator 122. The passivation layer 140 is disposed on the color filter 130, wherein a contact via W is formed in the color filter 130 and the passivation layer 140 such that a part of the switch 120 is exposed thereby. The pixel electrode 150 is disposed on the passivation layer 140 and electrically connected to the switch 120 through the contact via W.

In the present embodiment, the switch 120 is a bottom-gate TFT. In detail, the switch 120 includes a gate 120G, a source 120S, a drain 120D and a semiconductor layer 120C, wherein the gate 120G is disposed on a part of the sub-area 112 of the substrate 110. The gate insulator 122 covers the gate 120G and extends to the sub-area 112 of the substrate 110. The semiconductor layer 120C is disposed on the gate insulator 122 and located above the gate 120G. The source 120S and the drain 120D are respectively disposed on different areas of the semiconductor layer 120C, and respectively form favorable ohmic contact with the semiconductor layer 120C, wherein the gate 120G is connected with the scan line SL, and the source 120S is connected with the data line DL. A part of an area of the drain 120D is exposed by the contact via W and the drain 120D is electronically connected with the pixel electrode 150 through the contact via W. In the present embodiment, the pixel electrode 150 is, for example, transparent electrode, or transflective electrode.

As shown in FIG. 1, in the present embodiment, there is no other dielectric material between the color filter 130 and the gate insulator 122, therefore, the color filter 130 directly contacts the switch 120. Furthermore, the color filter 130 not only covers the gate insulator 122 but also covers the switch 120. In detail, the color filter 130 directly contacts the source 120S, the drain 120D, a part of the semiconductor layer 120C and the gate insulator 122. In the present embodiment, the color filter 130 includes a plurality of color filter films (such as red filter film, green filter film, blue filter film, etc.), and each of the color filters 130 is distributed correspondingly to one of the pixel electrodes 150. In the present embodiment, the distribution area of each color filter 130 is slightly greater than the distribution area of each pixel electrode 150, and each color filter 130 can be in stripe arrangement, delta arrangement or other arrangement for different color filter films.

In the present embodiment, the thickness of the gate insulator 122 is, for example, greater than or substantially equal to 3500 angstroms, but is not greater than about 4000 angstroms. When the thickness of the gate insulator 122 is greater than or substantially equal to 3500 angstroms but is not greater than about 4000 angstroms, the thickness of the passivation layer 140 is, for example, between about 900 to about 1100 angstroms. In other embodiment of the application, when the thickness of the gate insulator 122 is greater than or substantially equal to 3500 angstroms but is not greater than about 4000 angstroms, the thickness of the passivation layer 140 is, for example, between about 700 to about 1000 angstroms.

In a preferred embodiment, the thickness of the gate insulator 122 is about 3500 angstroms. When the thickness of the gate insulator 122 is substantially equal to 3500 angstroms, the thickness of the passivation layer 140 is, for example, between about 900 to about 1100 angstroms, or between about 700 to about 1000 angstroms.

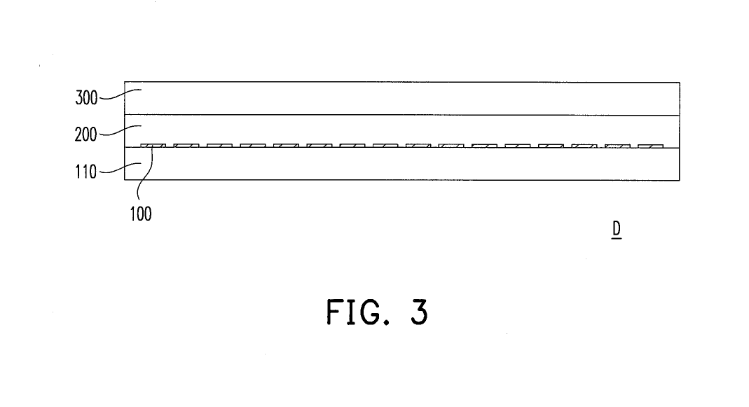

FIG. 3 is a schematic cross-sectional view of a display panel according to an embodiment of the present invention. Please refer to FIG. 3, a display panel D according to the present embodiment includes a plurality of pixel structures 100 described above, a display medium layer 200 and an opposite substrate 300. The display medium layer 200 is disposed on the pixel structures 100, and the opposite substrate 300 is disposed on the display medium layer 200. In the present embodiment, the material of the display medium layer 200 is, for example, liquid crystal material, self-illuminating material, electrophoresis material or electrowetting material.

When the display medium layer 200 is liquid crystal material, the display panel D needs to be combined with a backlight module (not illustrated) to be able to display images because the liquid crystal material is not self-illuminating material. When the display medium layer 200 is self-illuminating material, electrophoresis material or electrowetting material, the display panel D does not need to be combined with a backlight module to display images because the display medium layer 200 can illuminate itself or can reflect the light from the outside.

The pixel structure and the display panel of the application skip the manufacture of a protection layer between the color filter and the gate insulator, and therefore, the manufacturing cost can be further reduced.

### Experimental Embodiment 1

In the present experimental embodiment 1, the display panel is a transparent LCD panel, and the backlight module combined with the transparent LCD panel adopts cold cathode fluorescent lamp (CCFL) as light source. Moreover, in the transparent LCD panel, the pixel structure thereof is as illustrated in FIG. 1 and FIG. 2. The thickness of the gate insulator 122 is about 3500 angstroms. The Applicant changes the thickness of the passivation layer 140 and simulates red chroma coordinate, green chroma coordinate, blue chroma coordinate, white chroma coordinate, NTSC %, BL eff. and total eff. displayed by the transparent LCD panel. The simulation results are shown in Table 1, wherein PV2=100 represents the thickness of the passivation layer 140 (the material thereof is silicon nitride) is about 100 angstroms. STD represents the thickness of the passivation layer 140 is about 1000 angstroms (PV2=1000), and a protection layer (the material thereof is silicon nitride) exists between the color filter 130 and the gate insulator 122 and has a thickness of about 1000 angstroms.

TABLE 1

| Simulation | R | | | | G | | | | B | | | |
|---|---|---|---|---|---|---|---|---|---|---|---|---|
| Sim. | x | y | Y | ΔY | x | y | Y | ΔY | x | y | Y | ΔY |
| STD | 0.644 | 0.325 | 14.34 | — | 0.303 | 0.595 | 52.26 | — | 0.145 | 0.054 | 7.09 | — |
| PV2 = 100 | 0.645 | 0.325 | 14.42 | 0.57% | 0.305 | 0.594 | 50.21 | −3.93% | 0.146 | 0.052 | 6.69 | −5.72% |
| PV2 = 200 | 0.645 | 0.325 | 14.35 | 0.09% | 0.305 | 0.593 | 49.20 | −5.87% | 0.146 | 0.052 | 6.64 | −6.43% |
| PV2 = 300 | 0.645 | 0.325 | 14.30 | −0.28% | 0.305 | 0.592 | 48.38 | −7.43% | 0.146 | 0.052 | 6.65 | −6.31% |
| PV2 = 400 | 0.645 | 0.325 | 14.26 | −0.50% | 0.305 | 0.590 | 47.88 | −8.38% | 0.146 | 0.052 | 6.71 | −5.38% |
| PV2 = 500 | 0.644 | 0.324 | 14.26 | −0.53% | 0.305 | 0.589 | 47.76 | −8.62% | 0.146 | 0.051 | 6.82 | −3.86% |
| PV2 = 600 | 0.644 | 0.324 | 14.28 | −0.39% | 0.304 | 0.588 | 48.02 | −8.11% | 0.146 | 0.051 | 6.95 | −2.06% |
| PV2 = 700 | 0.644 | 0.324 | 14.32 | −0.08% | 0.304 | 0.589 | 48.64 | −6.94% | 0.146 | 0.052 | 7.06 | −0.40% |
| PV2 = 800 | 0.644 | 0.324 | 14.39 | 0.35% | 0.304 | 0.589 | 49.51 | −5.26% | 0.146 | 0.052 | 7.14 | 0.72% |
| PV2 = 900 | 0.644 | 0.324 | 14.46 | 0.83% | 0.304 | 0.591 | 50.52 | −3.34% | 0.145 | 0.053 | 7.16 | 1.01% |
| PV2 = 1000 | 0.645 | 0.324 | 14.52 | 1.31% | 0.304 | 0.592 | 51.48 | −1.50% | 0.145 | 0.053 | 7.12 | 0.42% |
| PV2 = 1100 | 0.645 | 0.325 | 14.58 | 1.71% | 0.305 | 0.594 | 52.21 | −0.10% | 0.145 | 0.053 | 7.03 | −0.87% |
| PV2 = 1200 | 0.645 | 0.325 | 14.62 | 1.97% | 0.305 | 0.595 | 52.56 | 0.57% | 0.145 | 0.054 | 6.91 | −2.55% |
| PV2 = 1300 | 0.646 | 0.325 | 14.63 | 2.05% | 0.306 | 0.596 | 52.44 | 0.35% | 0.145 | 0.053 | 6.79 | −4.21% |
| PV2 = 1400 | 0.646 | 0.325 | 14.61 | 1.93% | 0.307 | 0.596 | 51.89 | −0.71% | 0.146 | 0.053 | 6.70 | −5.51% |
| PV2 = 1500 | 0.646 | 0.325 | 14.57 | 1.64% | 0.307 | 0.595 | 51.03 | −2.37% | 0.146 | 0.052 | 6.65 | −6.21% |
| PV2 = 1600 | 0.645 | 0.325 | 14.51 | 1.20% | 0.307 | 0.593 | 50.02 | −4.29% | 0.146 | 0.052 | 6.65 | −6.20% |
| PV2 = 1700 | 0.645 | 0.324 | 14.44 | 0.70% | 0.306 | 0.592 | 49.05 | −6.14% | 0.146 | 0.051 | 6.70 | −5.51% |
| PV2 = 1800 | 0.644 | 0.324 | 14.36 | 0.18% | 0.305 | 0.590 | 48.28 | −7.62% | 0.146 | 0.051 | 6.79 | −4.31% |
| PV2 = 1900 | 0.644 | 0.324 | 14.30 | −0.27% | 0.305 | 0.589 | 47.80 | −8.54% | 0.146 | 0.051 | 6.89 | −2.88% |
| PV2 = 2000 | 0.644 | 0.324 | 14.25 | −0.62% | 0.304 | 0.588 | 47.68 | −8.77% | 0.146 | 0.051 | 6.98 | −1.57% |
| | | | | | Simulation | W | | | | | | |
| | | | | | Sim. | x | y | Y | ΔY | NTSC | BL eff. | total |
| | | | | | STD | 0.281 | 0.279 | 24.56 | — | 71.8 | — | — |
| | | | | | PV2 = 100 | 0.285 | 0.278 | 23.77 | −3.23% | 71.8 | 0.24% | −3.00% |
| | | | | | PV2 = 200 | 0.284 | 0.276 | 23.39 | −4.77% | 71.7 | 0.88% | −3.93% |
| | | | | | PV2 = 300 | 0.284 | 0.273 | 23.11 | −5.93% | 71.4 | 1.75% | −4.28% |
| | | | | | PV2 = 400 | 0.282 | 0.270 | 22.95 | −6.56% | 71.2 | 2.68% | −4.05% |
| | | | | | PV2 = 500 | 0.281 | 0.267 | 22.95 | −6.59% | 71.0 | 3.49% | −3.33% |
| | | | | | PV2 = 600 | 0.280 | 0.266 | 23.08 | −6.03% | 70.9 | 3.96% | −2.30% |
| | | | | | PV2 = 700 | 0.279 | 0.266 | 23.34 | −4.97% | 70.9 | 3.96% | −1.21% |
| | | | | | PV2 = 800 | 0.279 | 0.268 | 23.68 | −3.59% | 71.0 | 3.42% | −0.30% |
| | | | | | PV2 = 900 | 0.280 | 0.271 | 24.05 | −2.11% | 71.2 | 2.42% | 0.26% |
| | | | | | PV2 = 1000 | 0.281 | 0.275 | 24.38 | −0.77% | 71.4 | 1.15% | 0.38% |
| | | | | | PV2 = 1100 | 0.283 | 0.279 | 24.61 | 0.18% | 71.7 | −0.09% | 0.09% |
| | | | | | PV2 = 1200 | 0.285 | 0.282 | 24.70 | 0.54% | 71.9 | −1.02% | −0.49% |
| | | | | | PV2 = 1300 | 0.286 | 0.284 | 24.62 | 0.24% | 72.0 | −1.41% | −1.18% |
| | | | | | PV2 = 1400 | 0.287 | 0.283 | 24.40 | −0.66% | 72.0 | −1.18% | −1.82% |
| | | | | | PV2 = 1500 | 0.286 | 0.280 | 24.08 | −1.96% | 71.8 | −0.36% | −2.31 |
| | | | | | PV2 = 1600 | 0.285 | 0.276 | 23.73 | −3.41% | 71.6 | 0.85% | −2.59% |
| | | | | | PV2 = 1700 | 0.283 | 0.272 | 23.40 | −4.75% | 71.4 | 2.20% | −2.66% |
| | | | | | PV2 = 1800 | 0.281 | 0.268 | 23.14 | −5.79% | 71.2 | 3.40% | −2.58% |
| | | | | | PV2 = 1900 | 0.280 | 0.265 | 23.00 | −6.39% | 71.0 | 4.19% | −2.46% |
| | | | | | PV2 = 2000 | 0.279 | 0.264 | 22.97 | −6.49% | 70.9 | 4.41% | −2.37% |

As shown in Table 1, compared to STD (the thickness of the protection layer between the color filter 130 and the gate insulator 122 is about 1000 angstroms, PV2=1000), when the thickness of the passivation layer 140 is 900, 1000, and 1100 angstroms (PV2=900, PV2=1000, PV2=1100) and there is no dielectric layer between the color filter 130 and the gate insulator 122, the total eff. respectively are +0.26%, +0.38%, +0.09%. In other words, when the thickness of the gate insulator 122 is about 3500 angstroms and the backlight module adopts the CCFL as light source, the preferred thickness of the passivation layer 140 is between about 900 to about 1100 angstroms.

### Experimental Embodiment 2

In the present experimental embodiment 2, the display panel is a transparent LCD panel and the backlight module combined with the transparent LCD panel adopts white light emitting diode (white LED) as light source. The components of the white LED are, for example, blue LED chip, red fluorescent powder, green fluorescent powder, or other elements can be components of white light source. Moreover, in the transparent LCD panel, the pixel structure thereof is as illustrated in FIG. 1 and FIG. 2. The thickness of the gate insulator 122 is about 3500 angstroms. The Applicant changes the thickness of the passivation layer 140 and simulates red chroma coordinate, green chroma coordinate, blue chroma coordinate, white chroma coordinate, NTSC %, BL eff. and total eff. displayed by the transparent LCD panel. The simulation results are shown in Table 2, wherein PV2=100 represents the thickness of the passivation layer 140 (the material thereof is silicon nitride) is about 100 angstroms. STD represents the thickness of the passivation layer 140 is about 1000 angstroms (PV2=1000), and a protection layer (the material thereof is silicon nitride) exists between the color filter 130 and the gate insulator 122 and has a thickness of about 1000 angstroms.

TABLE 2

| Simulation | R | | | | G | | | | B | | | |
|---|---|---|---|---|---|---|---|---|---|---|---|---|
| Sim. | x | y | Y | ΔY | x | y | Y | ΔY | x | y | Y | ΔY |
| STD | 0.644 | 0.323 | 13.89 | — | 0.316 | 0.610 | 53.04 | — | 0.149 | 0.050 | 6.78 | — |
| PV2 = 100 | 0.645 | 0.324 | 13.89 | 0.04% | 0.318 | 0.607 | 49.84 | −6.03% | 0.149 | 0.048 | 6.39 | −5.81% |
| PV2 = 200 | 0.645 | 0.324 | 13.78 | −0.75% | 0.318 | 0.607 | 49.26 | −7.11% | 0.149 | 0.048 | 6.34 | −6.59% |
| PV2 = 300 | 0.645 | 0.323 | 13.69 | −1.39% | 0.317 | 0.607 | 48.96 | −7.68% | 0.149 | 0.048 | 6.34 | −6.57% |
| PV2 = 400 | 0.645 | 0.323 | 13.64 | −1.79% | 0.317 | 0.608 | 48.96 | −7.68% | 0.149 | 0.048 | 6.39 | −5.78% |
| PV2 = 500 | 0.644 | 0.323 | 13.62 | −1.92% | 0.316 | 0.608 | 49.27 | −7.11% | 0.150 | 0.047 | 6.49 | −4.38% |
| PV2 = 600 | 0.644 | 0.323 | 13.64 | −1.75% | 0.315 | 0.608 | 49.82 | −6.06% | 0.150 | 0.047 | 6.60 | −2.68% |
| PV2 = 700 | 0.644 | 0.323 | 13.70 | −1.32% | 0.315 | 0.608 | 50.54 | −4.70% | 0.149 | 0.047 | 6.71 | −1.05% |
| PV2 = 800 | 0.644 | 0.323 | 13.79 | −0.68% | 0.315 | 0.609 | 51.30 | −3.26% | 0.149 | 0.048 | 6.79 | 0.10% |
| PV2 = 900 | 0.644 | 0.323 | 13.90 | 0.09% | 0.316 | 0.609 | 51.97 | −2.01% | 0.149 | 0.048 | 6.82 | 0.52% |
| PV2 = 1000 | 0.644 | 0.323 | 14.01 | 0.87% | 0.317 | 0.608 | 52.41 | −1.17% | 0.149 | 0.049 | 6.79 | 0.12% |
| PV2 = 1100 | 0.645 | 0.323 | 14.10 | 1.57% | 0.318 | 0.608 | 52.55 | −0.92% | 0.149 | 0.049 | 6.72 | −0.98% |
| PV2 = 1200 | 0.646 | 0.324 | 14.17 | 2.06% | 0.319 | 0.608 | 52.35 | −1.29% | 0.149 | 0.050 | 6.61 | −2.50% |
| PV2 = 1300 | 0.646 | 0.324 | 14.20 | 2.29% | 0.320 | 0.607 | 51.86 | −2.21% | 0.149 | 0.049 | 6.51 | −4.08% |
| PV2 = 1400 | 0.646 | 0.324 | 14.19 | 2.21% | 0.321 | 0.607 | 51.18 | −3.49% | 0.149 | 0.049 | 6.42 | −5.39% |
| PV2 = 1500 | 0.646 | 0.324 | 14.14 | 1.83% | 0.321 | 0.606 | 50.44 | −4.90% | 0.149 | 0.048 | 6.36 | −6.18% |
| PV2 = 1600 | 0.646 | 0.323 | 14.06 | 1.22% | 0.321 | 0.606 | 49.76 | −6.19% | 0.150 | 0.048 | 6.35 | −6.33% |
| PV2 = 1700 | 0.645 | 0.323 | 13.95 | 0.45% | 0.319 | 0.606 | 49.24 | −7.15% | 0.150 | 0.047 | 6.39 | −5.84% |
| PV2 = 1800 | 0.645 | 0.323 | 13.84 | −0.36% | 0.318 | 0.606 | 48.97 | −7.67% | 0.150 | 0.047 | 6.45 | −4.85% |
| PV2 = 1900 | 0.644 | 0.322 | 13.73 | −1.10% | 0.317 | 0.607 | 48.98 | −7.65% | 0.150 | 0.047 | 6.54 | −3.62% |
| PV2 = 2000 | 0.644 | 0.322 | 13.65 | −1.68% | 0.315 | 0.607 | 49.25 | −7.14% | 0.149 | 0.047 | 6.62 | −2.44% |
| | | | | | Simulation | W | | | | | | |
| | | | | | Sim. | x | y | Y | ΔY | NTSC | BL eff. | Total eff. |
| | | | | | STD | 0.283 | 0.277 | 24.57 | — | 73.3 | — | — |
| | | | | | PV2 = 100 | 0.286 | 0.273 | 23.37 | −4.87% | 72.9 | 1.39% | −3.55% |
| | | | | | PV2 = 200 | 0.286 | 0.272 | 23.13 | −5.86% | 73.0 | 1.80% | −4.17% |
| | | | | | PV2 = 300 | 0.285 | 0.270 | 23.00 | −6.40% | 73.0 | 2.43% | −4.12% |
| | | | | | PV2 = 400 | 0.283 | 0.268 | 23.00 | −6.40% | 73.1 | 3.15% | −3.45% |
| | | | | | PV2 = 500 | 0.282 | 0.267 | 23.12 | −5.88% | 73.2 | 3.78% | −2.32% |
| | | | | | PV2 = 600 | 0.280 | 0.266 | 23.36 | −4.94% | 73.2 | 4.12% | −1.02% |
| | | | | | PV2 = 700 | 0.280 | 0.266 | 23.65 | −3.73% | 73.2 | 4.04% | 0.16% |
| | | | | | PV2 = 800 | 0.280 | 0.267 | 23.96 | −2.47% | 73.2 | 3.46% | 0.91% |
| | | | | | PV2 = 900 | 0.281 | 0.270 | 24.23 | −1.38% | 73.1 | 2.48% | 1.07% |
| | | | | | PV2 = 1000 | 0.283 | 0.273 | 24.40 | −0.67% | 73.1 | 1.32% | 0.65% |
| | | | | | PV2 = 1100 | 0.285 | 0.276 | 24.46 | −0.46% | 73.0 | 0.26% | −0.20% |
| | | | | | PV2 = 1200 | 0.287 | 0.278 | 24.38 | −0.77% | 72.8 | -0.44% | −1.20% |
| | | | | | PV2 = 1300 | 0.289 | 0.278 | 24.19 | −1.53% | 72.7 | -0.59% | −2.12% |
| | | | | | PV2 = 1400 | 0.289 | 0.277 | 23.93 | −2.59% | 72.7 | -0.16% | −2.75% |
| | | | | | PV2 = 1500 | 0.289 | 0.274 | 23.65 | −3.75% | 72.6 | 0.79% | −2.99% |
| | | | | | PV2 = 1600 | 0.287 | 0.271 | 23.39 | −4.80% | 72.7 | 2.07% | −2.84% |
| | | | | | PV2 = 1700 | 0.285 | 0.268 | 23.19 | −5.60% | 72.7 | 3.40% | −2.39% |
| | | | | | PV2 = 1800 | 0.283 | 0.265 | 23.09 | −6.03% | 72.9 | 4.48% | −1.82% |
| | | | | | PV2 = 1900 | 0.281 | 0.263 | 23.08 | −6.05% | 73.0 | 5.06% | −1.29% |
| | | | | | PV2 = 2000 | 0.280 | 0.263 | 23.17 | −5.68% | 73.2 | 4.97% | −0.99% |

As shown in Table 2, compared to STD (the thickness of the protection layer between the color filter 130 and the gate insulator 122 is about 1000 angstroms, PV2=1000), when the thickness of the passivation layer 140 is 700, 800, and 900, 1000 angstroms (PV2=700, PV2=800, PV2=900, PV2=1000) and there is no dielectric layer between the color filter 130 and the gate insulator 122, the total eff. respectively are +0.16%, +0.91%, +1.07%, +0.06%. In other words, when the thickness of the gate insulator 122 is about 3500 angstroms, the backlight module adopts the white LED as light source, and the white LED includes blue LED chip, red fluorescent powder and green fluorescent powder, the preferred thickness of the passivation layer 140 is between about 700 to about 1000 angstroms.

### Experimental Embodiment 3

In the present experimental embodiment 3, the display panel is a transparent LCD panel and the backlight module combined with the transparent LCD panel adopts white light emitting diode (white LED) as light source. The components of the white LED are, for example, blue LED chip and yellow fluorescent powder, or other elements can be components of the white light source. Moreover, in the transparent LCD panel, the pixel structure thereof is as illustrated in FIG. 1 and FIG. 2. The thickness of the gate insulator 122 is about 4000 angstroms. The Applicant changes the thickness of the passivation layer 140 and simulates red chroma coordinate, green chroma coordinate, blue chroma coordinate, white chroma coordinate, NTSC %, BL eff. and total eff. displayed by the transparent LCD panel. The simulation results are shown in Table 3, wherein PV2=100 represents the thickness of the passivation layer 140 (the material thereof is silicon nitride) is about 100 angstroms. STD represents the thickness of the passivation layer 140 is about 1000 angstroms (PV2=1000), a protection layer (the material thereof is silicon nitride) exists between the color filter 130 and the gate insulator 122 and has a thickness of about 1000 angstroms.

TABLE 3

| Simulation | R | | | | G | | | | B | | | |
|---|---|---|---|---|---|---|---|---|---|---|---|---|
| Sim. | x | y | Y | ΔY | x | y | Y | ΔY | x | y | Y | ΔY |
| STD | 0.623 | 0.327 | 11.66 | — | 0.331 | 0.611 | 54.79 | — | 0.154 | 0.039 | 6.07 | — |
| PV2 = 100 | 0.624 | 0.327 | 11.64 | −0.11% | 0.334 | 0.608 | 51.51 | −6.00% | 0.154 | 0.038 | 5.73 | −5.68% |
| PV2 = 200 | 0.624 | 0.327 | 11.55 | −0.89% | 0.333 | 0.609 | 50.91 | −7.09% | 0.154 | 0.038 | 5.68 | −6.44% |
| PV2 = 300 | 0.624 | 0.327 | 11.48 | −1.52% | 0.333 | 0.609 | 50.58 | −7.69% | 0.154 | 0.038 | 5.68 | −6.39% |
| PV2 = 400 | 0.623 | 0.326 | 11.43 | −1.91% | 0.332 | 0.609 | 50.57 | −7.72% | 0.154 | 0.038 | 5.73 | −5.57% |
| PV2 = 500 | 0.622 | 0.326 | 11.42 | −2.02% | 0.331 | 0.609 | 50.86 | −7.17% | 0.154 | 0.038 | 5.82 | −4.15% |
| PV2 = 600 | 0.622 | 0.326 | 11.44 | −1.85% | 0.331 | 0.610 | 51.43 | −6.15% | 0.154 | 0.038 | 5.92 | −2.47% |
| PV2 = 700 | 0.621 | 0.325 | 11.49 | −1.40% | 0.330 | 0.610 | 52.17 | −4.80% | 0.154 | 0.038 | 6.02 | −0.89% |
| PV2 = 800 | 0.621 | 0.325 | 11.57 | −0.76% | 0.331 | 0.610 | 52.96 | −3.35% | 0.154 | 0.038 | 6.08 | 0.20% |
| PV2 = 900 | 0.622 | 0.326 | 11.66 | 0.01% | 0.331 | 0.610 | 53.66 | −2.07% | 0.154 | 0.038 | 6.11 | 0.55% |
| PV2 = 1000 | 0.623 | 0.326 | 11.75 | 0.78% | 0.332 | 0.610 | 54.14 | −1.19% | 0.154 | 0.039 | 6.08 | 0.09% |
| PV2 = 1100 | 0.624 | 0.327 | 11.83 | 1.46% | 0.333 | 0.609 | 54.31 | −0.88% | 0.154 | 0.039 | 6.01 | −1.02% |
| PV2 = 1200 | 0.624 | 0.327 | 11.88 | 1.93% | 0.334 | 0.609 | 54.14 | −1.20% | 0.154 | 0.039 | 5.92 | −2.51% |
| PV2 = 1300 | 0.625 | 0.327 | 11.90 | 2.12% | 0.335 | 0.608 | 53.65 | −2.08% | 0.154 | 0.039 | 5.83 | −4.02% |
| PV2 = 1400 | 0.625 | 0.327 | 11.89 | 2.01% | 0.336 | 0.608 | 52.96 | −3.35% | 0.154 | 0.039 | 5.75 | −5.25% |
| PV2 = 1500 | 0.625 | 0.327 | 11.84 | 1.61% | 0.336 | 0.607 | 52.18 | −4.76% | 0.154 | 0.038 | 5.71 | −5.94% |
| PV2 = 1600 | 0.624 | 0.327 | 11.77 | 0.97% | 0.335 | 0.607 | 51.46 | −6.09% | 0.154 | 0.038 | 5.71 | −6.01% |
| PV2 = 1700 | 0.624 | 0.326 | 11.68 | 0.20% | 0.335 | 0.607 | 50.90 | −7.11% | 0.154 | 0.037 | 5.74 | −5.48% |
| PV2 = 1800 | 0.623 | 0.326 | 11.59 | −0.60% | 0.333 | 0.608 | 50.59 | −7.68% | 0.154 | 0.037 | 5.80 | −4.51% |
| PV2 = 1900 | 0.622 | 0.325 | 11.50 | −1.32% | 0.332 | 0.608 | 50.56 | −7.73% | 0.154 | 0.037 | 5.87 | −3.36% |
| PV2 = 2000 | 0.622 | 0.325 | 11.44 | −1.87% | 0.331 | 0.609 | 50.81 | −7.27% | 0.154 | 0.037 | 5.93 | −2.30% |
| | | | | | Simulation | W | | | | | | |
| | | | | | Sim. | x | y | Y | ΔY | NTSC | BL eff. | Tota eff. |
| | | | | | STD | 0.271 | 0.260 | 24.17 | — | 68.6 | — | — |
| | | | | | PV2 = 100 | 0.273 | 0.256 | 22.96 | −5.02% | 68.3 | 1.40% | −3.69% |
| | | | | | PV2 = 200 | 0.272 | 0.255 | 22.71 | −6.04% | 68.4 | 1.86% | −4.30% |
| | | | | | PV2 = 300 | 0.271 | 0.253 | 22.58 | −6.59% | 68.4 | 2.55% | −4.21% |
| | | | | | PV2 = 400 | 0.270 | 0.251 | 22.58 | −6.60% | 68.4 | 3.34% | −3.48% |
| | | | | | PV2 = 500 | 0.268 | 0.249 | 22.70 | −6.09% | 68.5 | 4.02% | −2.32% |
| | | | | | PV2 = 600 | 0.267 | 0.248 | 22.93 | −5.15% | 68.5 | 4.39% | −0.99% |
| | | | | | PV2 = 700 | 0.267 | 0.248 | 23.23 | −3.93% | 68.5 | 4.27% | 0.18% |
| | | | | | PV2 = 800 | 0.267 | 0.250 | 23.54 | −2.64% | 68.4 | 3.63% | 0.89% |
| | | | | | PV2 = 900 | 0.268 | 0.253 | 23.81 | −1.52% | 68.4 | 2.56% | 1.00% |
| | | | | | PV2 = 1000 | 0.270 | 0.256 | 23.99 | −0.77% | 68.4 | 1.30% | 0.52% |
| | | | | | PV2 = 1100 | 0.272 | 0.259 | 24.05 | −0.52% | 68.3 | 0.15% | −0.37% |
| | | | | | PV2 = 1200 | 0.274 | 0.261 | 23.98 | −0.81% | 68.3 | −0.59% | −1.39% |
| | | | | | PV2 = 1300 | 0.275 | 0.261 | 23.79 | −1.57% | 68.2 | 0.73% | −2.29% |
| | | | | | PV2 = 1400 | 0.275 | 0.260 | 23.53 | −2.65% | 68.1 | −0.23% | −2.87% |
| | | | | | PV2 = 1500 | 0.275 | 0.257 | 23.25 | −3.84% | 68.1 | 0.83% | −3.05% |
| | | | | | PV2 = 1600 | 0.273 | 0.254 | 22.98 | −4.95% | 68.1 | 2.21% | −2.84% |
| | | | | | PV2 = 1700 | 0.271 | 0.250 | 22.77 | −5.80% | 68.1 | 3.63% | −2.38% |
| | | | | | PV2 = 1800 | 0.269 | 0.247 | 22.66 | −6.28% | 68.1 | 4.76% | −1.81% |
| | | | | | PV2 = 1900 | 0.267 | 0.246 | 22.64 | −6.34% | 68.3 | 5.33% | −1.34% |
| | | | | | PV2 = 2000 | 0.267 | 0.246 | 22.73 | −5.99% | 68.4 | 5.18% | −1.12% |

As shown in Table 3, compared to STD (the thickness of the protection layer between the color filter 130 and the gate insulator 122 is about 1000 angstroms, PV2=1000), when the thickness of the passivation layer 140 is 700, 800, and 900, 1000 angstroms (PV2=700, PV2=800, PV2=900, PV2=1000) and there is no dielectric layer between the color filter 130 and the gate insulator 122, the total eff. respectively are +0.18%, +0.89%, +1.00%, +0.52%. In other words, when the thickness of the gate insulator 122 is about 4000 angstroms, the backlight module adopts the white LED as light source, and the white LED includes blue LED chip and yellow fluorescent powder, the preferred thickness of the passivation layer 140 is between about 700 to about 1000 angstroms.

Although the invention has been disclosed by the above embodiments, they are not intended to limit the invention. Those skilled in the art may make some modifications and alterations without departing from the spirit and scope of the invention. Therefore, the protection range of the invention falls in the appended claims.

What is claimed is:

1. A pixel structure comprising:
a substrate having at least one sub-area;
at least one switch disposed on the sub-area of the substrate, wherein the switch has a gate insulator that covers the sub-area of the substrate, and is electrically connected to at least one data line and at least one scan line;
at least one color filter disposed on the gate insulator, wherein the color filter is in contact with the switch and in contact with a part of the gate insulator;
a passivation layer disposed on the color filter, wherein at least one contact via is formed in the color filter and the passivation layer such that a part of the switch is exposed thereby; and
at least one pixel electrode disposed on the passivation layer and electrically connected to the part of the switch through the contact via.

2. The pixel structure of claim 1, wherein a thickness of the gate insulator is about 3500 angstroms.

3. The pixel structure of claim 1, wherein a thickness of the passivation layer is between about 900 to about 1100 angstroms.

4. The pixel structure of claim 1, wherein a thickness of the passivation layer is between about 700 to about 1000 angstroms.

5. The pixel structure of claim 1, wherein a thickness of the gate insulator is greater than or substantially equal to 3500 angstroms, and a thickness of the gate insulator is smaller than 4000 angstroms.

6. The pixel structure of claim 5, wherein a thickness of the passivation layer is between about 900 to about 1100 angstroms.

7. The pixel structure of claim 5, wherein a thickness of the passivation layer is between about 700 to about 1000 angstroms.

8. A display panel, comprising:
A plurality of pixel structures as claimed in claim 1;
a display medium layer, disposed on the pixel structures; and
an opposite substrate, disposed on the display medium layer.

9. The display panel of claim 8, wherein the material of the display medium layer includes liquid crystal material, self-illuminating material, electrophoresis material or electrowetting material.

10. The display panel of claim 8, wherein the color filter contacts the switch.

11. The display panel of claim 8, wherein a thickness of the gate insulator is about 3500 angstroms.

12. The display panel of claim 8, wherein a thickness of the passivation layer is between about 900 to about 1100 angstroms.

13. The display panel of claim 8, wherein a thickness of the passivation layer is between about 700 to about 1000 angstroms.

14. The display panel of claim 8, wherein a thickness of the gate insulator is greater than or substantially equal to 3500 angstroms, and a thickness of the gate insulator is smaller than 4000 angstroms.

15. The display panel of claim 14, wherein a thickness of the passivation layer is between about 900 to about 1100 angstroms.

16. The display panel of claim 14, wherein a thickness of the passivation layer is between about 700 to about 1000 angstroms.
